(19) United States
(12) Patent Application Publication
(10) Pub. No.: US 2025/0183184 A1
(43) Pub. Date: Jun. 5, 2025

(54) WIRING BOARD AND SEMICONDUCTOR DEVICE

(71) Applicant: SHINKO ELECTRIC INDUSTRIES CO., LTD., Nagano (JP)

(72) Inventors: Hiroshi TANEDA, Nagano (JP); Noriyoshi SHIMIZU, Nagano (JP); Yoko NAKABAYASHI, Nagano (JP)

(21) Appl. No.: 18/958,363

(22) Filed: Nov. 25, 2024

(30) Foreign Application Priority Data
Dec. 1, 2023 (JP) 2023-203835

(51) Int. Cl. H01L 23/538; H01L 21/48; H01L 25/16

(52) U.S. Cl. CPC H01L 23/5385; H01L 21/4857; H01L 23/5386; H01L 25/16

(57) ABSTRACT

A wiring board has a first interconnect structure including a first interconnect layer, a first insulating layer, and an electronic component embedded in the first insulating layer, and a second interconnect structure including a second interconnect layer and a second insulating layer, and laminated on one side of the first interconnect structure. The second interconnect layer has an interconnect density higher than an interconnect density of the first interconnect layer. The first interconnect layer includes a pad having a portion exposed from the first insulating layer. In a plan view, the first insulating layer includes a first region in which the pad is disposed, and a second region located on an outer periphery of the first region. The electronic component is disposed in the second region, and is electrically connected to the second interconnect layer.

### CROSS-REFERENCE TO RELATED APPLICATIONS

This application is based upon and claims priority to Japanese Patent Application No. 2023-203835, filed on Dec. 1, 2023, the entire contents of which are incorporated herein by reference.

### FIELD

Certain aspects of the embodiments discussed herein are related to wiring boards and semiconductor devices.

### BACKGROUND

When providing a semiconductor chip on a wiring board, the semiconductor chip is attached via an interconnect structure which serves as an interposer with fine wiring, for example. The interposer includes a silicon substrate, a glass substrate, an organic substrate, or the like. A technique for embedding an electronic component in such a wiring board is proposed (refer to International Publication Pamphlet No. WO 2021/084750, for example). In such a wiring board, it is preferable to efficiently dissipate heat generated by the electronic component.

### SUMMARY

Accordingly, it is an object in one aspect of the embodiments to improve dissipation of heat generated by an electronic component in a wiring board embedded with the electronic component.

According to one aspect of the embodiments, a wiring board includes a first interconnect structure including a first interconnect layer, a first insulating layer, and an electronic component embedded in the first insulating layer; and a second interconnect structure including a second interconnect layer and a second insulating layer, and laminated on one side of the first interconnect structure, wherein the second interconnect layer has an interconnect density higher than an interconnect density of the first interconnect layer, the first interconnect layer includes a pad having a portion exposed from the first insulating layer, in a plan view, the first insulating layer includes a first region in which the pad is disposed, and a second region located on an outer periphery of the first region, and the electronic component is disposed in the second region, and is electrically connected to the second interconnect layer.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a plan view illustrating an example of a wiring board according to a first embodiment;

FIG. 2 is a cross sectional view illustrating the example of the wiring board according to the first embodiment;

FIG. 3A, FIG. 3B, FIG. 3C, and FIG. 3D are diagrams (part 1) illustrating an example of a manufacturing process of the wiring board according to the first embodiment;

FIG. 4A, FIG. 4B, FIG. 4C, and FIG. 4D are diagrams (part 2) illustrating the example of the manufacturing process of the wiring board according to the first embodiment;

FIG. 5A, FIG. 5B, and FIG. 5C are diagrams (part 3) illustrating the example of the manufacturing process of the wiring board according to the first embodiment;

FIG. 6A and FIG. 6B are diagrams illustrating an example of the manufacturing process of the wiring board according to a first modification of the first embodiment;

FIG. 7A, FIG. 7B, FIG. 7C, and FIG. 7D are diagrams illustrating an example of the manufacturing process of the wiring board according to a second modification of the first embodiment;

FIG. 8 is a plan view illustrating an example of the wiring board according to a third modification of the first embodiment;

FIG. 9 is a plan view illustrating an example of the wiring board according to a fourth modification of the first embodiment;

FIG. 10 is a cross sectional view illustrating an example of the wiring board according to a fifth modification of the first embodiment; and

FIG. 11 is a cross sectional view illustrating an example of a semiconductor device according to an application example of the first embodiment.

### DESCRIPTION OF EMBODIMENTS

Preferred embodiments of the present invention will be described with reference to the accompanying drawings. In the drawings, those constituent elements that are the same are designated by the same reference numerals, and a redundant description thereof may be omitted.

### First Embodiment

### [Structure of Wiring Board]

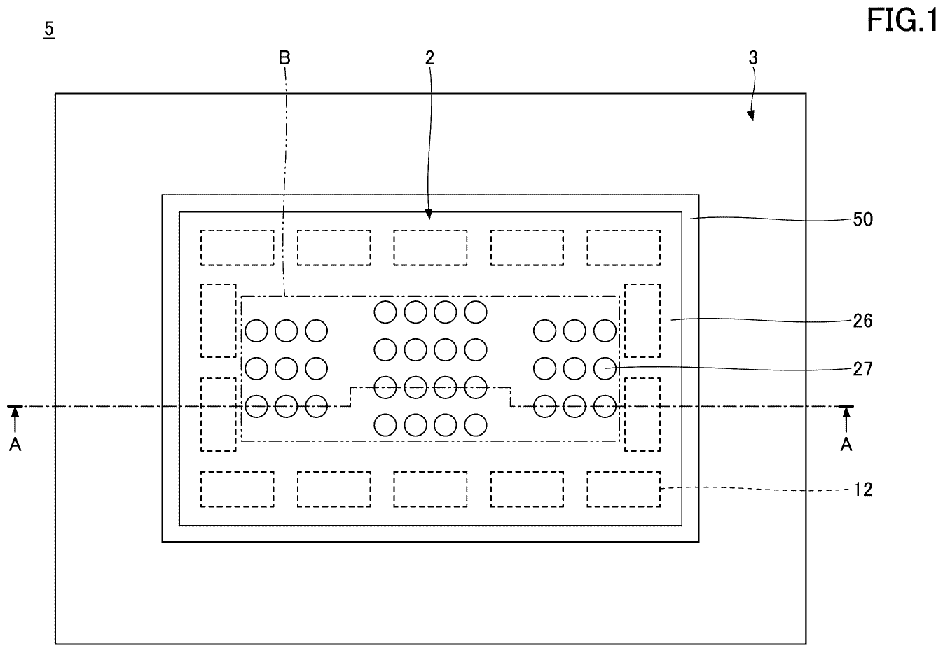

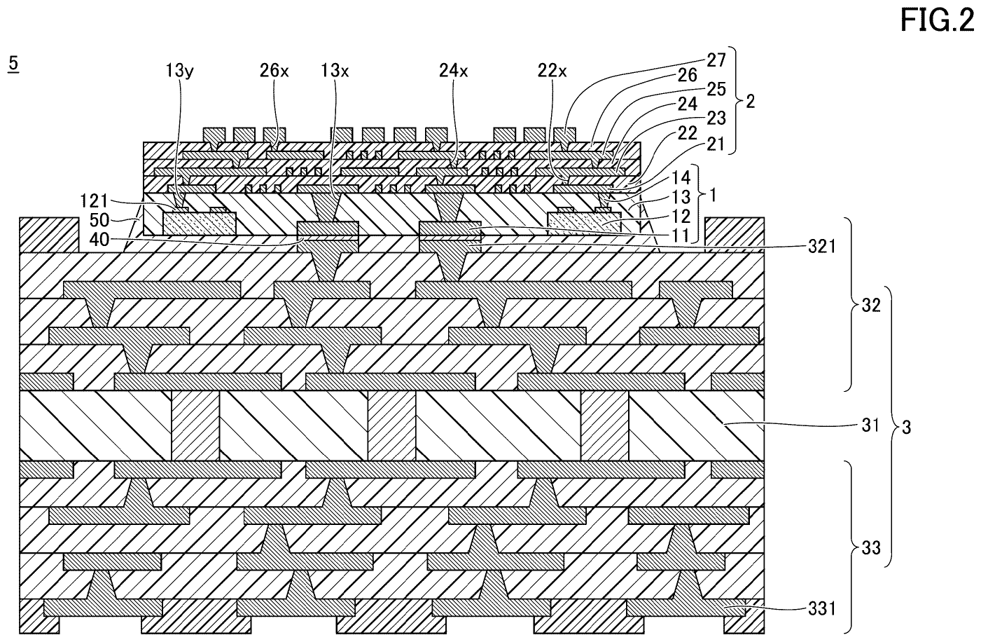

FIG. 1 is a plan view illustrating an example of a wiring board according to a first embodiment. FIG. 2 is a cross sectional view illustrating the example of the wiring board according to the first embodiment. FIG. 2 illustrates a cross section taken along a line A-A in FIG. 1. For the sake of convenience, an electronic component 12 is illustrated in the cross sectional view of FIG. 2 as being wider than in FIG. 1. The same applies to the other cross sectional views.

As illustrated in FIG. 1 and FIG. 2, a wiring board 5 includes a first interconnect structure 1, a second interconnect structure 2, and a third interconnect structure 3. The second interconnect structure 2 is laminated on one side of the first interconnect structure 1 in a thickness direction. The third interconnect structure 3 is laminated on the other side of the first interconnect structure 1 in the thickness direction. That is, the third interconnect structure 3 is disposed on the opposite side from the second interconnect structure 2, with respect to the first interconnect structure 1 interposed therebetween. The wiring board 5 may be configured by the first interconnect structure 1 and the second interconnect structure 2. That is, the third interconnect structure 3 of the wiring board 5 may be omitted.

In the present embodiment, for the sake of convenience, the side of the wiring board 5 provided with an interconnect layer 27 in FIG. 1 may be referred to as an upper side or one side, and the side of the wiring board 5 provided with an interconnect layer 331 may be referred to as a lower side or the other side. The interconnect layer 27 and the interconnect layer 331 will be described later. However, the wiring board 5 can be used in an upside-down state or can be disposed at an arbitrary angle. Moreover, a plan view refers to a view of an object, viewed from above, in a normal direction with respect to an upper surface of an insulating layer 26. A planar shape refers to a shape of an object in the plan view, viewed from above, in the normal direction with respect to the upper surface of the insulating layer 26. The insulating layer 26 will be described later.

The first interconnect structure 1 is an interconnect structure in which an interconnect layer and an insulating layer are laminated, and includes an electronic component embedded in the insulating layer. The interconnect layer of the first interconnect structure 1 may be referred to as a first interconnect layer, the insulating layer of the first interconnect structure 1 may be referred to as a first insulating layer, and a via interconnect of the first interconnect structure 1 may be referred to as a first via interconnect. In the example illustrated in FIG. 2, the first interconnect structure 1 includes an interconnect layer 11 as the first interconnect layer, an insulating layer 13 as the first insulating layer, and a via interconnect 14 as the first via interconnect. In the first interconnect structure 1, the number of layers of each of the first interconnect layer, the first insulating layer, and the first via interconnect is not limited to that of the example illustrated in FIG. 2.

In the first interconnect structure 1, the interconnect layer 11 is embedded in a lower surface of the insulating layer 13. The interconnect layer 11 includes a portion exposed from the insulating layer 13. Specifically, a lower surface of the interconnect layer 11 is exposed from the lower surface of the insulating layer 13, and an upper surface and a side surface of the interconnect layer 11 are covered with the insulating layer 13. In the example illustrated in FIG. 2, the lower surface of the interconnect layer 11 coincides with the lower surface of the insulating layer 13. However, the lower surface of the interconnect layer 11 may be recessed toward the via interconnect 14 than the lower surface of the insulating layer 13.

The lower surface of the interconnect layer 11, exposed from the lower surface of the insulating layer 13, is formed in a circular shape in the plan view, for example, and can be used as a pad for making an electrical connection to the third interconnect structure 3. That is, the interconnect layer 11 includes pads having a portion thereof exposed from the insulating layer 13. The interconnect layer 11 may include an interconnect pattern in addition to the pads. A material used for the interconnect layer 11 may be copper (Cu) or the like, for example. The interconnect layer 11 may have a laminated structure composed of a plurality of metal layers. A thickness of the interconnect layer 11 may be in a range of approximately 10 μm to approximately 35 μm. A line-and-space (hereinafter also referred to as a “line/space”) of the interconnect layer 11 may be in a range of approximately 10 μm/10 μm to approximately 50 μm/50 μm, for example.

A line of the line/space represents an interconnect width, and a space of the line-space represents a spacing between adjacent interconnects (or interconnect spacing). For example, in a case where the line/space is described as being in a range of 10 μm/10 μm to 50 μm/50 μm, it is indicated that the interconnect width is 10 μm or greater and 50 μm or less, and that the interconnect spacing between the adjacent interconnects is 10 μm or greater and 50 μm or less. The interconnect width and the interconnect spacing does not necessarily have to be the same.

In the plan view, the insulating layer 13 includes a first region where the pads of the interconnect layer 11 are disposed, and a second region located on an outer periphery of the first region. A two-dot chain line in FIG. 1 indicates an example of a boundary B between the first region and the second region. The first region is disposed on an inner side of the boundary B, and the second region is disposed on an outer side of the boundary B. The two-dot chain line indicating the boundary B is a virtual line that is illustrated for the sake of convenience, and the line does not actually exist. In the first interconnect structure 1, the electronic component 12 is embedded in the insulating layer 13. The electronic component 12 is disposed in the second region. That is, the electronic component 12 is disposed at a position that does not interfere with a layout of the pads of the interconnect layer 11, on the outer periphery of the region where the pads of the interconnect layer 11 are disposed in the plan view. The electronic component 12 includes an electrode 121 on the side of the second interconnect structure 2.

The electronic component 12 may be a passive component or an active component, or a combination of the passive component and the active component. The electronic component 12 is an integrated passive device (IPD), a semiconductor chip, a capacitor, an inductor, a resistor, or the like, for example. A thickness of the electronic component 12, excluding the electrode 121, and may be in a range of approximately 50 μm to approximately 100 μm, for example. A thickness of the electrode 121 may be in a range of approximately 5 μm to approximately 10 μm, for example. A thermal expansion coefficient of the electronic component 12 is smaller than a thermal expansion coefficient of the insulating layer 13.

Accordingly, in the wiring board 5, the insulating layer 13 of the first interconnect structure 1 includes, in the plan view, the first region where the pads of the interconnect layer 11 are disposed, and the second region located on the outer periphery of the first region. The electronic component 12 is disposed in the second region. Hence, heat generated by the electronic component 12 can easily escape outside the insulating layer 13, thereby improving a heat dissipation of the heat generated by the electronic component 12.

The first interconnect structure 1 is mounted on the third interconnect structure 3 using bonding members 40 (which will be described later), such as solder or the like. When mounting the first interconnect structure 1, the first interconnect structure 1 is heated and thus thermally contracts, but the thermal contraction of the first interconnect structure 1 during the mounting is smaller on the side of the first region (center side) than on the side of the second region (outer peripheral side) of the insulating layer 13. For this reason, by disposing the pads of the interconnect layer 11 in the first region where the thermal contraction is small, a positional deviation of the pads of the interconnect layer 11 during the mounting is reduced, and thus, a pitch of the pads of the interconnect layer 11 can be narrowed.

In addition, because the electronic component 12 is embedded in the insulating layer 13 of the first interconnect structure 1, a distance in the thickness direction between the electronic component 12 and a semiconductor chip that is mounted on the second interconnect structure 2 can be reduced. In addition, because an electrical path between the electronic component 12 and the semiconductor chip or the like can be reduced, a resistance loss can be reduced. As a result, a power supply efficiency can be improved, and a power supply can be stabilized. Moreover, signal characteristics can be improved.

Further, the electronic component 12 having the thermal expansion coefficient smaller than that of the insulating layer 13 is disposed on the outer peripheral side of the region of the insulating layer 13 where the pads of the interconnect layer 11 are disposed, and thus, a rigidity of the first interconnect structure 1 can be increased. Hence, warpage, expansion, and contraction of the first interconnect structure 1 caused by the heating can be reduced, when mounting the first interconnect structure 1 on the third interconnect structure 3. In addition, as a result of reducing the warpage, expansion, and contraction of the first interconnect structure 1, a mounting accuracy can be improved when mounting the first interconnect structure 1 on the third interconnect structure 3. Further, as a result of reducing the warpage, expansion, and contraction of the first interconnect structure 1, the positional deviation of the pads of the interconnect layer 11 during the mounting can further be reduced, and thus, the pitch of the pads of the interconnect layer 11 can further be narrowed.

One or more electronic components 12 may be disposed in the second region, but from a viewpoint of reducing the warpage, expansion, and contraction of the first interconnect structure 1, a plurality of electronic components 12 are preferably disposed in the second region. In the example illustrated in FIG. 1, fourteen electronic components 12 are disposed in the second region. In addition, from a viewpoint of uniformly reducing the warpage, expansion, and contraction of the first interconnect structure 1, the plurality of electronic components 12 are preferably arranged point symmetrically with respect to a center of the insulating layer 13 in the plan view.

In the example illustrated in FIG. 1, the insulating layer 13 has a rectangular shape in the plan view. The shape of the insulating layer 13 is substantially the same as the shape of the insulating layer 26 illustrated in FIG. 1. As illustrated in FIG. 1, in the case where the insulating layer 13 has the rectangular shape in the plan view, the plurality of electronic components 12 are preferably disposed so as to be scattered in a picture-frame shape along each side of the rectangular shape. In this case, because the plurality of electronic components 12 function as stiffeners, the warpage, expansion, and contraction of the first interconnect structure 1 can further be reduced. As a result, the mounting accuracy when mounting the first interconnect structure 1 on the third interconnect structure 3 can be improved, and the pitch of the pads of the interconnect layer 11 can further be narrowed.

The insulating layer 13 is formed so as to cover the upper surface and the side surface of the interconnect layer 11. The insulating layer 13 is formed so as to cover an upper surface and a side surface of the electronic component 12. A lower surface of the electronic component 12 and the lower surfaces of the pads of the interconnect layer 11 are exposed from the lower surface of the insulating layer 13. The lower surface of the electronic component 12 and the lower surfaces of the pads of the interconnect layer 11 may coincide with the lower surface of the insulating layer 13, for example.

The insulating layer 13 is an insulating layer including a non-photosensitive resin as a main component, for example. The insulating layer 13 may include a thermosetting non-photosensitive resin, such as an epoxy-based resin, an imide-based resin, a phenol-based resin, a cyanate-based resin, or the like as a main component, for example. A thickness of the insulating layer 13 is preferably greater than a total thickness of the electronic component 12 and the electrode 121. The insulating layer 13 may include a filler, such as silica (SiO₂) or the like. In addition, the insulating layer 13 may include a reinforcing member, such as glass fiber or the like.

The insulating layer 13 includes via holes 13x which penetrate the insulating layer 13 and expose an upper surface of the interconnect layer 11. The insulating layer 13 also includes via holes 13y which penetrate the insulating layer 13 and expose upper surfaces of the electrodes 121 of the electronic components 12. The via holes 13x may have an inverted truncated cone shape such that a diameter of the via hole 13x that opens toward the second interconnect structure 2 is larger than a diameter of a bottom surface of the via hole 13x formed by the upper surface of the interconnect layer 11. The via holes 13y may have an inverted truncated cone shape such that a diameter of the via hole 13y that opens toward the second interconnect structure 2 is larger than a diameter of a bottom surface of the via hole 13y formed by the upper surface of the electrode 121.

The via interconnect 14 fills the via holes 13x and the 13y. The via interconnect 14 does not have a portion extending to the upper surface of the insulating layer 13. An upper surface of the via interconnect 14 is exposed from the upper surface of the insulating layer 13. The upper surface of the via interconnect 14 coincides with the upper surface of the insulating layer 13, for example. The upper surface of the via interconnect 14 and the upper surface of the insulating layer 13 are polished surfaces. For this reason, the upper surface of the via interconnect 14 and the upper surface of the insulating layer 13 are smooth surfaces (low roughness surfaces) with little irregularities. The roughness of the upper surface of the via interconnect 14 and the upper surface of the insulating layer 13 may be set in a range of approximately 15 nm to approximately 40 nm in terms of a surface roughness Ra.

The second interconnect structure 2 is an interconnect structure in which an interconnect layer and an insulating layer are laminated. The interconnect layer of the second interconnect structure 2 may be referred to as a second interconnect layer, the insulating layer of the second interconnect structure 2 may be referred to as a second insulating layer, and a via interconnect of the second interconnect structure 2 may be referred to as a second via interconnect. In the example illustrated in FIG. 2, the second interconnect structure 2 includes interconnect layers 21, 23, 25, and 27 as the second interconnect layers, and insulating layers 22, 24, and 26 as the second insulating layers. In the second interconnect structure 2, the number of layers of each of the second interconnect layers and the second insulating layers is not limited to that of the example illustrated in FIG. 2.

An interconnect width and an interconnect spacing of the second interconnect layer of the second interconnect structure 2 are smaller than the interconnect width and the interconnect spacing of the first interconnect layer of the first interconnect structure 1. That is, the second interconnect layer is a fine interconnect layer having an interconnect density higher than an interconnect density of the first interconnect layer. A total thickness of the second interconnect structure 2 may be in a range of approximately 80 μm to approximately 100 μm, for example. In this case, the total thickness of the second interconnect structure 2 is a distance in the thickness direction from the lower surface of the insulating layer 22 to the upper surface of the interconnect layer 27.

The interconnect layer 21 is a pad and/or an interconnect pattern formed on the upper surface of the insulating layer 13 and the upper surface of the via interconnect 14. A portion of the lower surface of the interconnect layer 21 makes contact with the upper surface of the via interconnect 14, and the interconnect layer 21 and the via interconnect 14 are electrically connected. That is, the via interconnect 14 is directly connected to the interconnect layer 21 which is the lowermost second interconnect layer. The interconnect layer 21 includes portions electrically connected to the interconnect layer 11 through the via interconnect 14. The interconnect layer 21 also includes portions electrically connected to the electrodes 121 of the electronic components 12 through the via interconnect 14. A material used for the interconnect layer 21 may mainly be copper or the like, for example. A thickness of the interconnect layer 21 may be in a range of approximately 1 μm to approximately 10 μm, for example. A line/space of the interconnect pattern of the interconnect layer 21 may be in a range of approximately 1 μm/1 μm to approximately 8 μm/8 μm, for example.

The insulating layer 22 is provided on the upper surface of the insulating layer 13, and covers an upper surface and a side surface of the interconnect layer 21. The insulating layer 22 is an insulating layer including a photosensitive insulating resin as a main component, for example. Examples of the photosensitive insulating resin include a phenol-based resin, a polyimide-based resin, or the like, for example. The insulating layer 22 may include a filler, such as silica (SiO₂) or the like. The insulating layer 22 is thinner than the insulating layer 13. A thickness of the insulating layer 22 may be in a range of approximately 3 μm to approximately 20 μm, for example. The insulating layer 22 includes via holes 22x which penetrate the insulating layer 22 and reach the upper surface of the interconnect layer 21.

The interconnect layer 23 is formed on one side of the insulating layer 22, and is electrically connected to the interconnect layer 21. The interconnect layer 23 fills the via holes 22x, and extends to an upper surface of the insulating layer 22. Portions of the interconnect layer 23 filling the via holes 22x form a via interconnect, and portions of the interconnect layer 23 extending on the upper surface of the insulating layer 22 form pads and/or an interconnect pattern. A material used for the interconnect layer 23, a thickness of the interconnect pattern of the interconnect layer 23, and a line/space of the interconnect pattern of the interconnect layer 23 may be the same as those of the interconnect layer 21, for example.

The insulating layer 24 is provided on one surface of the insulating layer 22, and covers an upper surface and a side surface of the interconnect layer 23. A material used for the insulating layer 24 and a thickness of the insulating layer 24 may be the same as those of the insulating layer 22, for example. The insulating layer 24 may include a filler, such as silica (SiO₂) or the like. The insulating layer 24 includes via holes 24x which penetrate the insulating layer 24 and reach the upper surface of the interconnect layer 23.

The interconnect layer 25 is formed on one side of the insulating layer 24, and is electrically connected to the interconnect layer 23. The interconnect layer 25 fills the via holes 24x, and extends to an upper surface of the insulating layer 24. Portions of the interconnect layer 25 filling the via holes 24x form a via interconnect, and portions of the interconnect layer 25 extending on the upper surface of the insulating layer 24 forms pads and/or an interconnect pattern. A material used for the interconnect layer 25, a thickness of the interconnect pattern of the interconnect layer 25, and a line/space of the interconnect pattern of the interconnect layer 25 may be the same as those of the interconnect layer 21, for example.

The insulating layer 26 is provided on one surface of the insulating layer 24, and covers an upper surface and a side surface of the interconnect layer 25. A material used for the insulating layer 26 and a thickness of the insulating layer 26 may be the same as those of the insulating layer 24, for example. The insulating layer 26 may include a filler, such as silica (SiO₂) or the like. The insulating layer 26 includes via holes 26x which penetrate the insulating layer 26 and reach the upper surface of the interconnect layer 25.

The interconnect layer 27 is formed on one side of the insulating layer 26, and is electrically connected to the interconnect layer 25. The interconnect layer 27 fills the via holes 26x, and extends to an upper surface of the insulating layer 26. Portions of the interconnect layer 27 filling the via holes 26x form a via interconnect, and portions of the interconnect layer 27 extending on the upper surface of the insulating layer 26 form electrodes for external connection. A material used for the interconnect layer 27 may be the same as that of the interconnect layer 21, for example. A thickness of the electrodes of the interconnect layer 27 may be approximately 50 μm, for example. The electrodes of the interconnect layer 27 can be used for making an electrical connection to an electronic component, such as a semiconductor chip or the like. The interconnect layer 27 may be electrically connected to the electrodes 121 of the electronic component 12 through the interconnect layer 25, the interconnect layer 23, the interconnect layer 21, and the via interconnect 14.

The third interconnect structure 3 is an interconnect structure in which an interconnect layer and an insulating layer are laminated. The interconnect layer of the third interconnect structure 3 may be referred to as a third interconnect layer, and the insulating layer of the third interconnect structure 3 may be referred to as a third insulating layer. In the third interconnect structure 3, the number of layers of each of the third interconnect layer and the third insulating layer is not limited to the example illustrated in FIG. 2.

An interconnect width and an interconnect spacing of the second interconnect layer forming the second interconnect structure 2 are smaller than the interconnect width and the interconnect spacing of the third interconnect layer forming the third interconnect structure 3. That is, the second interconnect layer is a fine interconnect layer having an interconnect density higher than an interconnect density of the third interconnect layer. A line/space of the third interconnect layer may be in a range of approximately 10 μm/10 μm to approximately 20 μm/20 μm, for example.

The third interconnect structure 3 is required to have pads or the like to be connected to the first interconnect structure 1, and may have a structure similar to that of a known build-up wiring board, for example. In the example illustrated in FIG. 2, the third interconnect structure 3 is a multilayer wiring board in which a first laminate 32 is laminated on one side of a core layer 31 and a second laminate 33 is laminated on the other side of the core layer 31. In each of the first laminate 32 and the second laminate 33, an interconnect layer and an insulating layer are successively laminated from the side of the core layer 31, and a solder resist layer is formed on an outermost layer.

The first laminate 32 includes, as a lowermost interconnect layer, an interconnect layer 321 including pads. The pads of the interconnect layer 321 are electrically connected to the pads of the interconnect layer 11 of the first interconnect structure 1 through the bonding members 40. The bonding members 40 are solder bumps, for example. A material used for the solder bumps may be SnBi solder or the like, for example.

A bonding layer 50 may be formed between the upper surface of the third interconnect structure 3 and the lower surface of the first interconnect structure 1. A material used for the bonding layer 50 may be an epoxy-based insulating resin, for example. The bonding layer 50 can be formed by laminating a film of an insulating thermosetting resin called a non-conductive film (NCF) on the lower surface of the first interconnect structure 1, for example, and thermally curing the film when the first interconnect structure 1 is mounted on the third interconnect structure 3.

Because the bonding layer 50 is formed between the upper surface of the third interconnect structure 3 and the lower surface of the first interconnect structure 1, and the bonding layer 50 makes direct contact with the insulating layer 13. Accordingly, the heat generated by the electronic component 12 can easily escape from the insulating layer 13 toward the bonding layer 50, thereby further improving the heat dissipation of the first interconnect structure 1.

The second laminate 33 includes, as a lowermost interconnect layer, an interconnect layer 331 including pads. The pads of the interconnect layer 331 can be used for making electrical connection to a mounting board, such as a mother board or the like.

### [Method for Manufacturing Wiring Board]

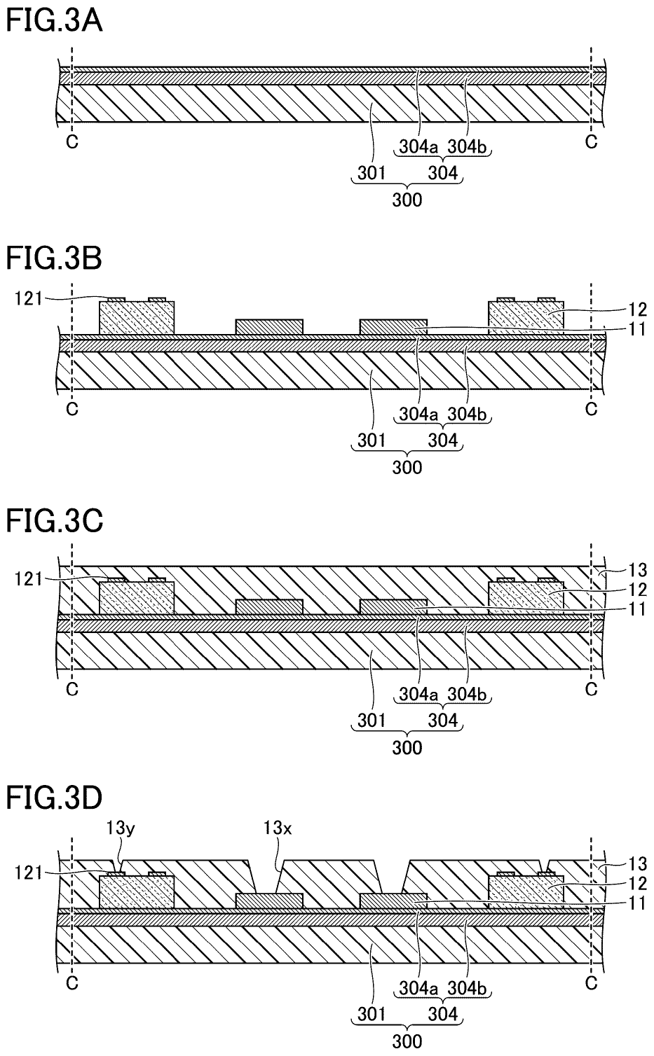

Next, a method for manufacturing the wiring board according to the first embodiment will be described. FIG. 3A through FIG. 5C are diagrams illustrating an example of a manufacturing process of the wiring board according to the first embodiment. Although the example described hereinafter forms a layer structure only on one side of a support, the layer structure may be formed on one side and the other side of the support. In FIG. 3A through FIG. 5C, a broken line C indicates a position where the structure is cut and singulated into individual wiring boards. A region located between the adjacent broken lines C in the cross sectional view is finally singulated into one individual wiring board.

First, in a process (or step) illustrated in FIG. 3A, a support 300 is prepared. The support 300 has a structure in which a carrier-attached copper foil 304 is laminated on one side of a core substrate 301, for example. The core substrate 301 is a resin substrate having a thickness of approximately 0.7 mm, for example, and may include a reinforcing member, such as glass fiber or the like. The carrier-attached copper foil 304 has a structure including a thin foil 304a and a thick foil (or carrier foil) 304b. More particularly, the thin foil 304a formed of copper (Cu) and having a thickness in a range of approximately 1.5 μm to approximately 5 μm, for example, is releasably (or detachably) attached to the thick foil 304b formed of copper (Cu) and having a thickness in a range of approximately 10 μm to approximately 50 μm, for example, via a release layer (not illustrated). The thick foil 304b is provided as a support member for facilitating handling of the thin foil 304a.

The structure of the support 300 described above is merely an example, and the support 300 is not limited thereto. For example, the support 300 may include a laminate in which a plurality of prepregs are laminated, in place of the core substrate 301. In addition, the support 300 may have a structure in which the carrier-attached copper foil 304 is disposed on one side of a glass substrate, a metal substrate, or the like via a release layer.

Next, in a process (or step) illustrated in FIG. 3B, the interconnect layer 11 is formed on the support 300. Specifically, a resist layer, having openings at portions where the interconnect layer 11 is to be formed, is formed on the upper surface of the carrier-attached copper foil 304 (upper surface of the thin foil 304a), using a dry film resist or the like. Next, an electrolytic plating layer is formed, as the interconnect layer 11, on the upper surface of the carrier-attached copper foil 304 exposed inside the openings in the resist layer, by electrolytic plating using the carrier-attached copper foil 304, which is a metal layer, as a power supply layer. The material used for the interconnect layer 11 and the thickness of the interconnect layer 11 are as described above. Thereafter, the resist layer is stripped and removed.

Next, the electronic components 12 including the electrodes 121 are prepared, and the electronic components 12 are disposed face-up on the outer peripheral side of the region surrounded by the broken line C on the upper surface of the carrier-attached copper foil 304. The electronic components 12 may be disposed directly on the upper surface of the carrier-attached copper foil 304 or may be disposed on the carrier-attached copper foil 304 via a bonding layer.

Next, in a process (or step) illustrated in FIG. 3C, the insulating layer 13, which covers the interconnect layer 11 and the electronic component 12, is formed on the upper surface of the carrier-attached copper foil 304 of the support 300. Specifically, first, an insulating resin film in a semi-cured state and including a thermosetting resin as a main component, for example, is prepared. Then, this insulating resin film is laminated on the upper surface of the carrier-attached copper foil 304, and cured while applying heat and pressure to form the insulating layer 13. Alternatively, instead of laminating the insulating resin film, a liquid or paste of the insulating resin may be coated on the upper surface of the carrier-attached copper foil 304, and then cured to form the insulating layer 13. The material used for the insulating layer 13 and the thickness of the insulating layer 13 are as described above.

In general, when applying the heat and pressure to the insulating resin in the semi-cured state, the softened insulating resin flows out, and thus, an outer periphery of the insulating layer 13 is likely to become thin due to an insufficient amount (or lack) of the resin. However, in the wiring board 5, the electronic component 12 is disposed on the outer periphery of the insulating layer 13, and an amount of resin required on the outer periphery can be reduced. For this reason, a variation in the thickness of the insulating layer 13 from the center side toward the outer periphery of the insulating layer 13 can be reduced.

Next, in a process (or step) illustrated in FIG. 3D, the via holes 13x are formed in the insulating layer 13 to penetrate the insulating layer 13 and expose the upper surface of the interconnect layer 11. Further, the via holes 13y are formed in the insulating layer 13 to penetrate the insulating layer 13 and expose the upper surfaces of the electrodes 121 of the electronic components 12. The via holes 13x and 13y may be formed by a laser beam machining using a CO-laser, a YAG laser, an excimer laser, or the like, for example.

The via hole 13x may have an inverted truncated cone shape such that a diameter of the via hole 13x that opens toward the upper surface of the insulating layer 13 is larger than a diameter of a bottom surface of the via hole 13x formed by the upper surface of the interconnect layer 11. The via hole 13y may have an inverted truncated cone shape such that a diameter of the via hole 13y that opens toward the upper surface of the insulating layer 13 is larger than a diameter of a bottom surface of the via hole 13y formed by the upper surface of the electrode 121. After forming the via holes 13x and 13y, a desmear process is preferably performed to remove resin residue adhered to the upper surface of the interconnect layer 11 exposed at the bottom of each via hole 13x and resin residue adhered to the upper surface of the electrode 121 exposed at the bottom of each via hole 13y, respectively.

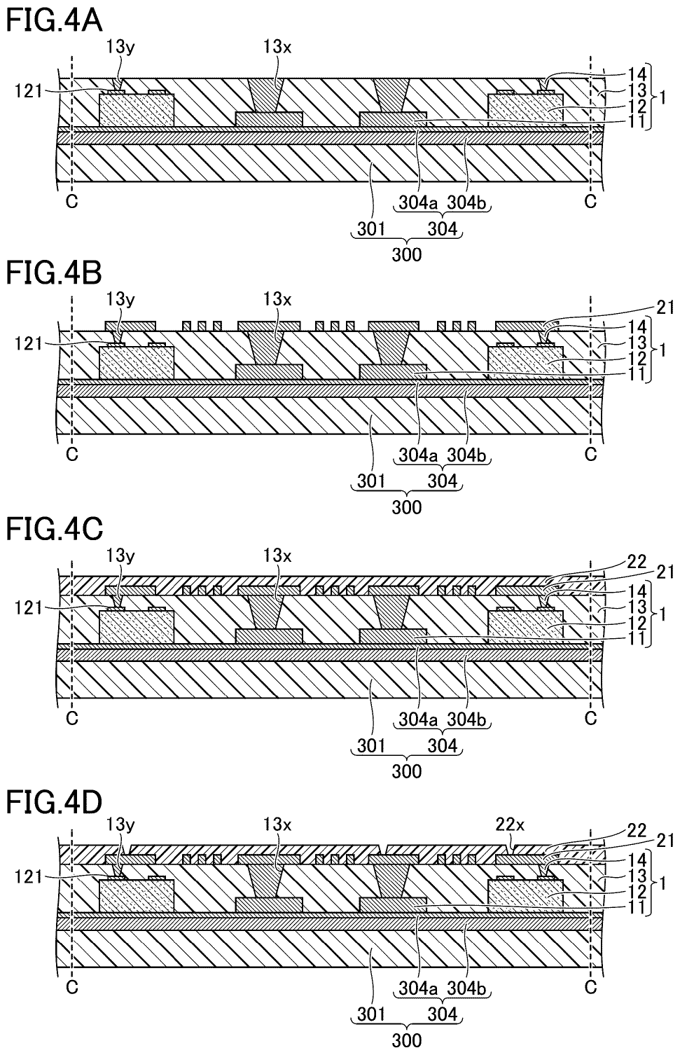

Next, in a process (or step) illustrated in FIG. 4A, the via interconnect 14 is formed to fill each of the via holes 13x and 13y. The via interconnect 14 may be formed by a method in which a semi-additive method and polishing are combined, for example. Specifically, a seed layer is formed by electroless plating of copper (Cu) or sputtering of copper (Cu) to continuously cover the upper surface of the insulating layer 13, inner side surfaces of the via holes 13x and 13y, and the upper surfaces of the interconnect layer 11 and the electrodes 121 exposed at the bottom of the via holes 13x and 13y, for example. Next, an electrolytic plating layer filling the via holes 13x and 13y and extending on the upper surface of the insulating layer 13 is formed by electrolytic plating, using the seed layer as a power supply layer. Thereafter, the electrolytic plating layer extending on the upper surface of the insulating layer 13 is removed by polishing, and the upper surface of the insulating layer 13 and the upper surface of the electrolytic plating layer are planarized. The upper surface of the insulating layer 13 may be polished together with the electrolytic plating layer. Accordingly, the via interconnect 14 filling the via holes 13x and 13y is formed. For example, a chemical mechanical polishing (CMP) can be used for the polishing. The upper surface of the via interconnect 14 and the upper surface of the insulating layer 13 after the polishing may have a surface roughness Ra in a range of approximately 15 nm to approximately 40 nm, for example. The lower surface of the insulating layer 13 has a surface roughness Ra in a range of approximately 180 nm to approximately 280 nm, for example. The first interconnect structure 1 is completed by the processes (or steps) described above.

Next, in a process (or step) illustrated in FIG. 4B, the interconnect layer 21 is formed on the upper surface of the via interconnect 14 and the upper surface of the insulating layer 13. A portion of the lower surface of the interconnect layer 21 makes contact with the upper surface of the via interconnect 14, and the two are electrically connected. The interconnect layer 21 may be formed by a semi-additive method, for example.

Next, in a process (or step) illustrated in FIG. 4C, the insulating layer 22 is formed on the upper surface of the insulating layer 13 to cover the upper surface and the side surface of the interconnect layer 21. Specifically, an uncured insulating resin film, which covers the upper surface and the side surface of the interconnect layer 21, is laminated on the upper surface of the insulating layer 13, for example. Then, this insulating resin film is pressed against the insulating layer 13 while being heated, and is cured to form the insulating layer 22. In this case, in order to reduce the skin effect, it is preferable to select an insulating resin film having an upper surface with a low surface roughness Ra of 30 nm or less. It is more preferable to select an insulating resin film having an upper surface with a low surface roughness Ra of 20 nm or less, and even more preferable to select an insulating resin film having an upper surface with a low surface roughness Ra of 10 nm or less. Instead of laminating the insulating resin film, the insulating layer 22 may be formed by coating a liquid or paste of the insulating resin and then curing the resin. In a case where the surface roughness of the upper surface of the insulating layer 22 is high, it is preferable to smoothen the upper surface of the insulating layer 22 by a chemical mechanical polishing (CMP) or the like to reduce the skin effect, so that the surface roughness of the upper surface of the insulating layer 22 assumes the preferable values described above. The material used for the insulating layer 22 and the thickness of the insulating layer 22 are as described above.

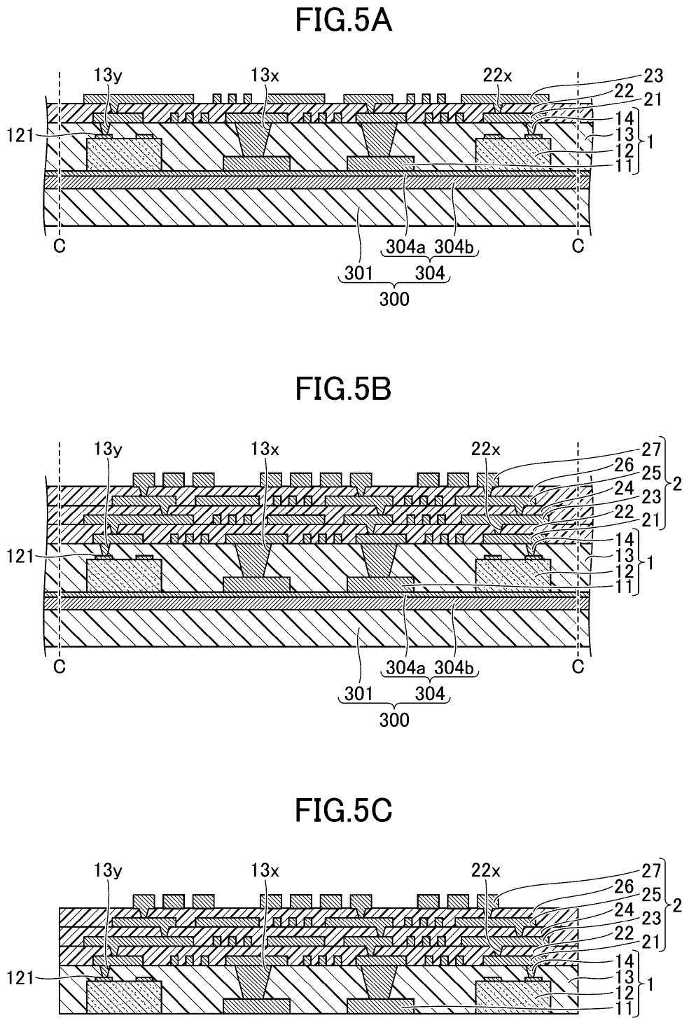

Next, in a process (or step) illustrated in FIG. 4D, the via holes 22x penetrating the insulating layer 22 and exposing the upper surface of the interconnect layer 21 are formed. The via holes 22x may be formed by the same method used to form the via holes 13x, for example. Next, in a process (or step) illustrated in FIG. 5A, the interconnect layer 23 is formed on the insulating layer 22. The interconnect layer 23 may be formed by a semi-additive method, for example. Next, in a process (or step) illustrated in FIG. 5B, processes that are the same as those illustrated in FIG. 4C, FIG. 4D, and FIG. 5A are repeated to successively form the insulating layer 24, the interconnect layer 25, the insulating layer 26, and the interconnect layer 27. Thus, the second interconnect structure 2 is completed by the processes (or steps) described above.

Next, in a process (or step) illustrated in FIG. 5C, after the support 300 illustrated in FIG. 5B is removed, the structure is cut and singulated into individual wiring boards. When removing the support 300, first, the core substrate 301 and the thick foil 304b are mechanically stripped from the thin foil 304a. Then, the thin foil 304a is removed by a wet etching using a ferric chloride aqueous solution, a cupric chloride aqueous solution, an ammonium persulfate aqueous solution, or the like, for example. Thereafter, the portion, which is removed of the support 300 from the structure illustrated in FIG. 5B, is cut along the broken line C using a dicer or the like, and is singulated. Thus, a plurality of laminated bodies of the first interconnect structure 1 and the second interconnect structure 2 illustrated in FIG. 5C can be obtained. The order of removing the support 300 and the singulating the structure may be reversed.

After the process (or step) illustrated in FIG. 5C, the third interconnect structure 3 is prepared, and the third interconnect structure 3 and the first interconnect structure 1 are electrically connected. The third interconnect structure 3 may be manufactured by a well known build-up method, for example. After the third interconnect structure 3 is prepared, the interconnect layer 321 forming the first laminate 32 of the third interconnect structure 3 and the interconnect layer 11 of the first interconnect structure 1 are bonded via the bonding members 40, such as solder bumps or the like. The bonding layer 50 is provided between the third interconnect structure 3 and the first interconnect structure 1, as required. Thus, the wiring board 5 is completed by the processes (or steps) described above. Because the warpage, expansion, and contraction of the first interconnect structure 1 in which the electronic components 12 are embedded in the insulating layer 13 can be reduced, the mounting accuracy can be improved when mounting the first interconnect structure 1 on the third interconnect structure 3.

### First Modification of First Embodiment

In a first modification of the first embodiment, an example of the method of manufacturing the wiring board different from the first embodiment will be described. In the first modification of the first embodiment, those constituent elements that are the same as those of the embodiment described above may be omitted.

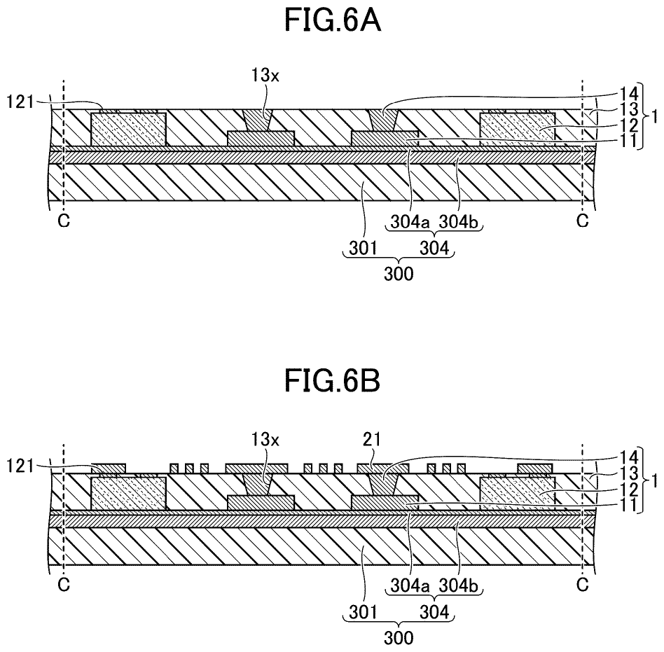

FIG. 6A and FIG. 6B are diagrams illustrating an example of the manufacturing process of the wiring board according to the first modification of the first embodiment. The processes (or steps) of the first embodiment illustrated in FIG. 4A and FIG. 4B may be replaced with processes (or steps) of the first modification illustrated in FIG. 6A FIG. 6B.

In the process (or step) illustrated in FIG. 6A, first, the via interconnect 14 is formed to fill each of the via holes 13x and 13y. Then, the upper surfaces of the insulating layer 13 and the via interconnect 14 are polished. The polishing is performed until all of the via interconnect 14 filling the via holes 13y are removed and the upper surfaces of the electrodes 121 of the electronic components 12 are exposed. Thus, the upper surface of the insulating layer 13, the upper surfaces of the electrodes 121, and the upper surface of the via interconnect 14 filling the via holes 13x can coincide with one another. Thereafter, in the process (or step) illustrated in FIG. 6B, the interconnect layer 21 is formed on the upper surface of the via interconnect 14 and the upper surface of the insulating layer 13, in the same manner as the process illustrated in FIG. 4B. A portion of the lower surface of the interconnect layer 21 is directly connected to the upper surface of the via interconnect 14 filling the via hole 13x. In addition, a portion of the lower surface of the interconnect layer 21 is directly connected to the upper surface of the electrode 121. The subsequent processes (or steps) are the same as the processes (or steps) illustrated in FIG. 4C and subsequent figures of the first embodiment.

Accordingly, the electrode 121 of the electronic component 12 may be directly connected to the interconnect layer 21 which is the second interconnect layer. Thus, a height (or thickness) of the first interconnect structure 1 can be reduced by the removed amount of the via interconnect 14 filling the via hole 13y.

### Second Modification of First Embodiment

In a second modification of the first embodiment, an example of the method of manufacturing the wiring board different from the first embodiment will be described. In the second modification of the first embodiment, those constituent elements that are the same as those of the embodiment described above may be omitted.

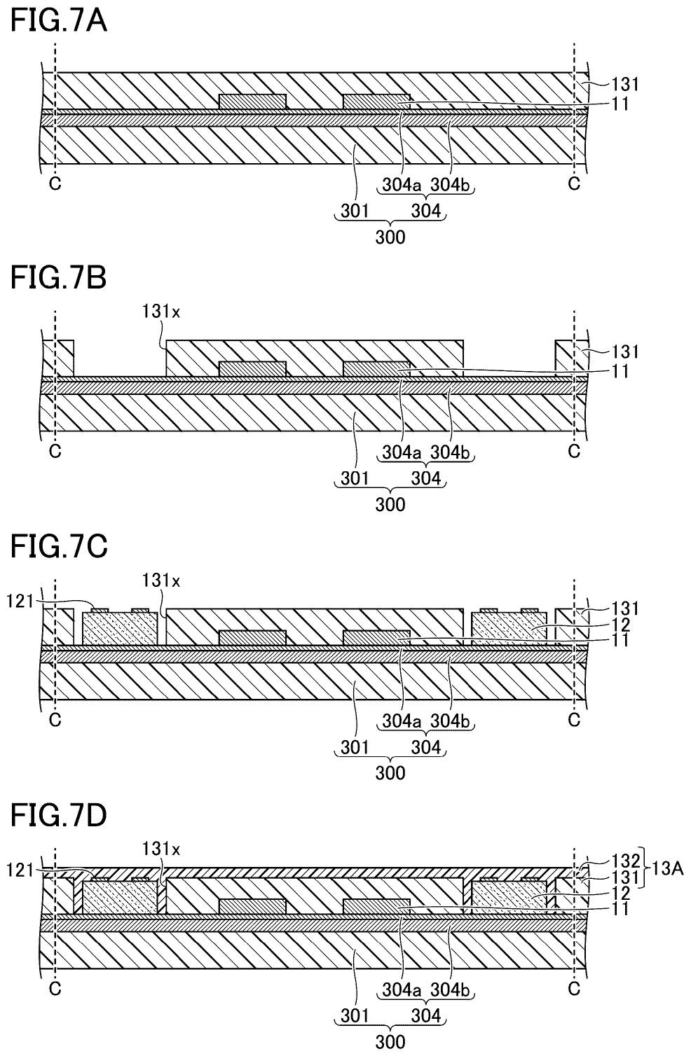

FIG. 7A through FIG. 7D are diagrams illustrating an example of the manufacturing process of the wiring board according to the second modification of the first embodiment. The processes (or steps) of the first embodiment illustrated in FIG. 3A through FIG. 3C may be replaced with the processes (or steps) of the second modification illustrated in FIG. 7A through FIG. 7D.

In the process (or step) illustrated in FIG. 7A, first, the interconnect layer 11 is formed on the support 300, and further, the insulating layer 131 is formed so as to cover the interconnect layer 11. The material used for the insulating layer 131 and the method of forming the insulating layer 131 may be the same as those of the insulating layer 13 of the first embodiment. The insulating layer 131 is preferably thinner than the insulating layer 13, so that a thickness of an insulating layer 13A which will be described later is substantially the same as the thickness of the insulating layer 13.

Next, in a process (or step) illustrated in FIG. 7B, through hole 131x, which penetrate the insulating layer 131 and expose the upper surface of the support 300, are formed in the insulating layer 131. The through holes 131x may be formed by a laser beam machining using a CO₂ laser or the like, for example. A cavity for mounting the electronic component 12 is formed by the upper surface of the support 300 and an inner side surface of the through hole 131x.

Next, in a process (or step) illustrated in FIG. 7C, the electronic components 12 including the electrodes 121 are prepared, and the electronic components 12 are disposed face-up on the upper surface of the carrier-attached copper foil 304 exposed inside the through holes 131x. The electronic components 12 may be disposed directly on the upper surface of the carrier-attached copper foil 304 or may be disposed via an bonding layer.

Next, in a process (or step) illustrated in FIG. 7D, an embedding resin 132 is formed to fill the through holes 131x to cover the electronic components 12, and to extend upward from the through holes 131x to cover the upper surface of the insulating layer 131. Specifically, the embedding resin 132 is formed by laminating a film of an epoxy-based resin or the like in a semi-cured state, for example, so as to cover the electronic components 12, and curing the film of the epoxy-based resin or the like. Alternatively, instead of laminating the film of the epoxy-based resin or the like, a liquid or paste of the epoxy-based resin or the like may be coated on the electronic components 12, and cured to form the embedding resin 132. The insulating layer 131 and the embedding resin 132 form the insulating layer 13A. The material used for the embedding resin 132 may be the same as that used for the insulating layer 13 of the first embodiment. The embedding resin 132 may be formed of a material different from that of the insulating layer 13. The embedding resin 132 preferably has a thickness so that a thickness of the insulating layer 13A becomes substantially the same as thickness of the insulating layer 13. The subsequent processes (or steps) are the same as the processes (or steps) illustrated in FIG. 3D and subsequent figures of the first embodiment.

Accordingly, the insulating layer 13 may be formed after the electronic components 12 are disposed on the support 300. Alternatively, the insulating layer 131 having the through holes 131x may be formed on the support 300, the electronic components 12 may be disposed inside the through holes 131x, and the embedding resin 132 may be formed. The wiring board 5 having the same performance can be manufactured by any of the manufacturing methods described above.

### Third and Fourth Modifications of First Embodiment

In third and fourth modifications of the first embodiment, examples of preferable positions where the electronic components are disposed, when the number of electronic components is relatively small, are illustrated. In the third and fourth modifications of the first embodiment, those constituent elements that are the same as those of the embodiment described above may be omitted.

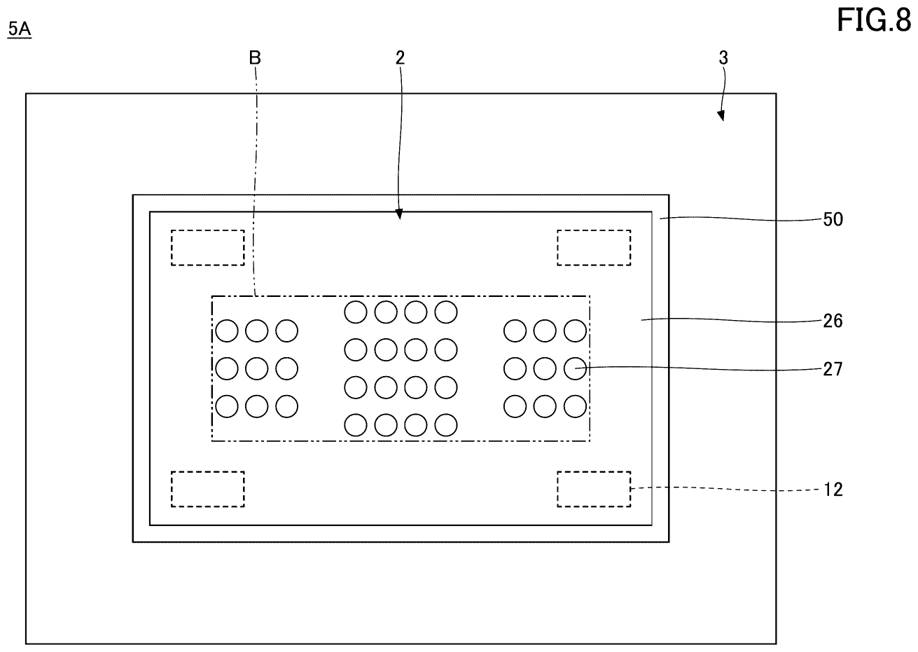

FIG. 8 is a plan view illustrating an example the wiring board according to the third modification of the first embodiment. In the example of a wiring board 5A illustrated in FIG. 8, the insulating layer 13 has a rectangular shape in the plan view. The planar shape of the insulating layer 13 is substantially the same as the planar shape of the insulating layer 26 illustrated in FIG. 8. As illustrated in FIG. 8, in the case where the insulating layer 13 has the rectangular shape in the plan view and four electronic components 12 are to be disposed, the electronic components 12 are preferably disposed at four corners of the rectangular shape. In this case, it is possible to uniformly and effectively reduce the warpage, expansion, and contraction of the first interconnect structure 1.

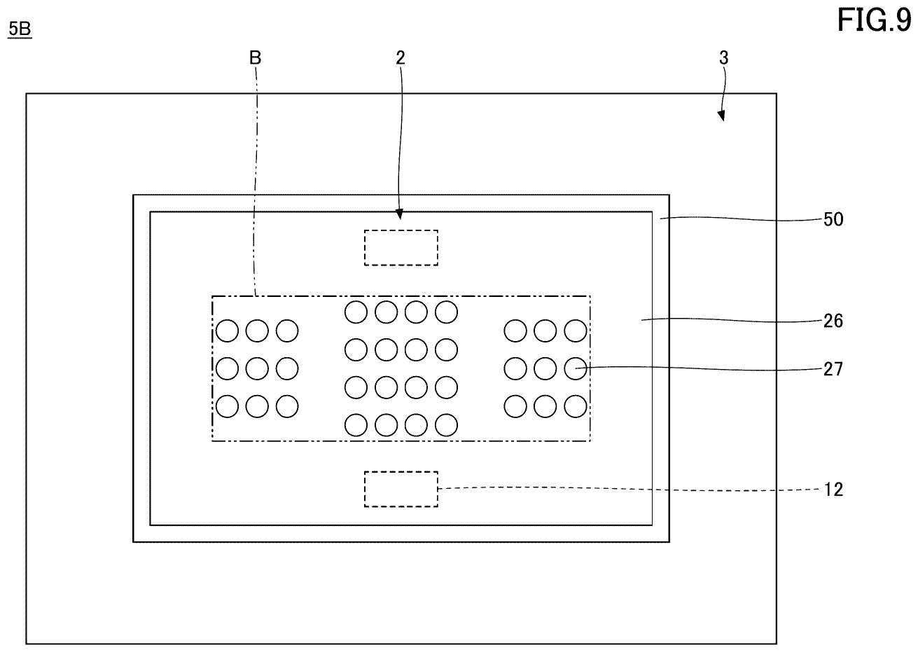

FIG. 9 is a plan view illustrating an example of the wiring board according to the fourth modification of the first embodiment. In the example of a wiring board 5B illustrated in FIG. 9, the insulating layer 13 has a rectangular shape in the plan view. The planar shape of the insulating layer 13 is substantially the same as the planar shape of the insulating layer 26 illustrated in FIG. 9. As illustrated in FIG. 9, in a case where the insulating layer 13 has the rectangular shape in the plan view and two electronic components 12 are to be disposed, the electronic components 12 are preferably disposed on two sides along the long sides of the rectangular shape so as to face each other. In this case, it is possible to uniformly and effectively reduce the warpage, expansion, and contraction of the first interconnect structure 1.

### Fifth Modification of First Embodiment

In a fifth modification of the first embodiment, an example of the wiring board having a plurality of first interconnect structures and a plurality of second interconnect structures is illustrated. In the fifth modification of the first embodiment, those constituent elements that are the same as those of the embodiment described above may be omitted.

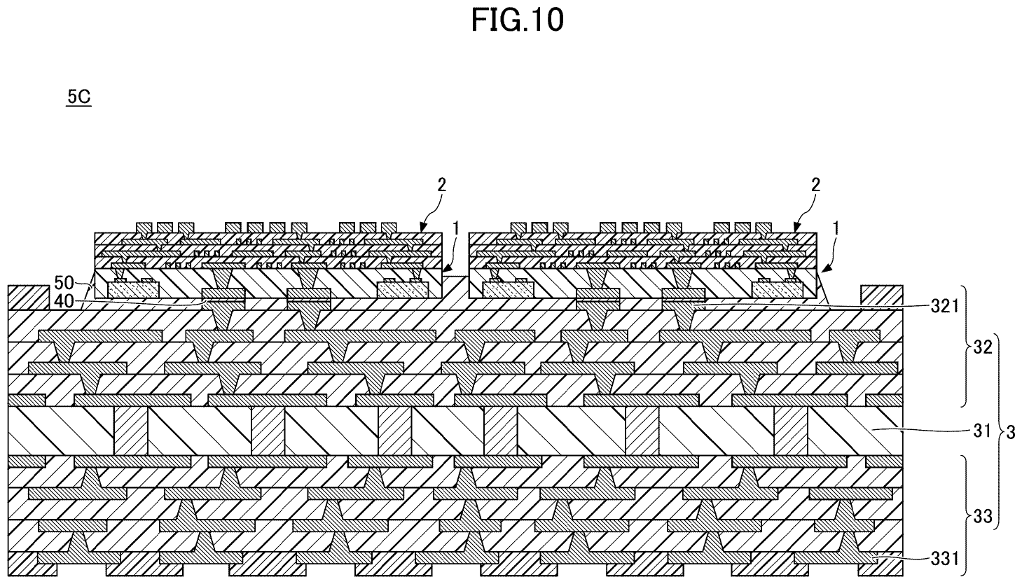

FIG. 10 is a cross sectional view illustrating an example of the wiring board according to the fifth modification of the first embodiment. The example of a wiring board 5C illustrated in FIG. 10 differs from the wiring board 5 in that two laminates of the first interconnect structure 1 and the second interconnect structure 2 are disposed on one side of the third interconnect structure 3. The number of laminates of the first interconnect structure 1 and the second interconnect structure 2 may be three or more.

Accordingly, by disposing a plurality of laminates of the first interconnect structure 1 and the second interconnect structure 2, a larger number of semiconductor chips can be mounted on the wiring board 5C.

### Application Example of First Embodiment

In an application example of the first embodiment, an example of a semiconductor device in which a semiconductor chip is mounted on the wiring board will be described. In the application example of the first embodiment, those constituent elements that are the same as those of the embodiment described above may be omitted.

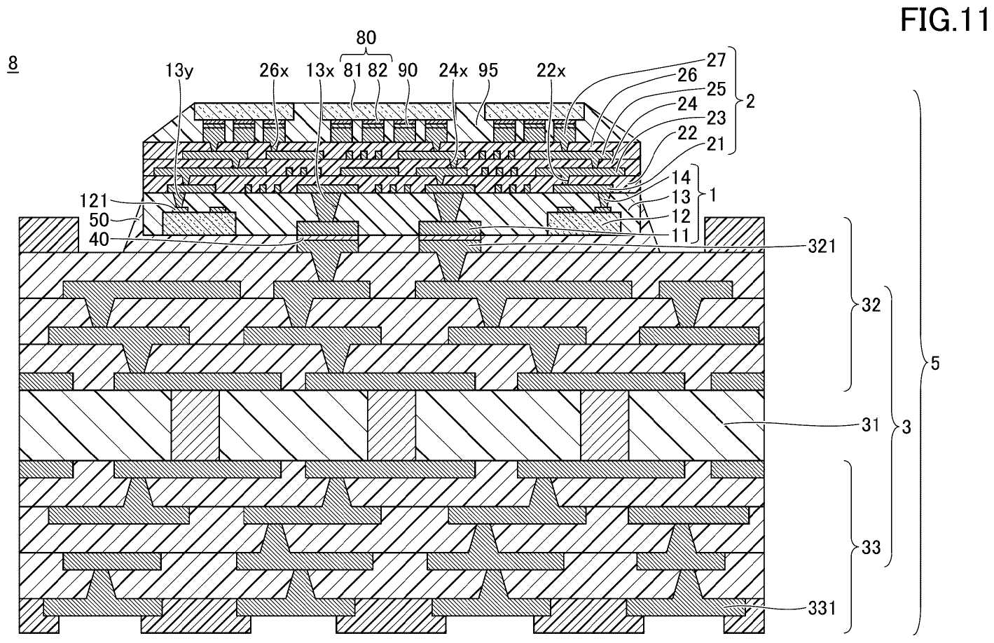

FIG. 11 is a cross sectional view illustrating an example of the semiconductor device according to the application example of the first embodiment. As illustrated in FIG. 11, a semiconductor device 8 includes the wiring board 5 illustrated in FIG. 1, a semiconductor chip 80, and an underfill resin 95. The semiconductor chip 80 is mounted on the second interconnect structure 2 of the wiring board 5.

The semiconductor chip 80 includes a semiconductor integrated circuit (not illustrated) or the like formed on a thinned semiconductor substrate 81 formed of silicon or the like, for example. Electrode pads 82, electrically connected to the semiconductor integrated circuit (not illustrated), are formed on a circuit formation surface of the semiconductor substrate 81.

The electrode pads 82 of the semiconductor chip 80 are electrically connected to electrodes forming the interconnect layer 27 of the second interconnect structure 2 through bumps 90. The underfill resin 95 is filled between the circuit formation surface of the semiconductor substrate 81 of the semiconductor chip 80 and the upper surface of the second interconnect structure 2, and covers a portion or all of a side surface of the semiconductor chip 80. The bumps 90 are solder bumps, for example. Examples of a material used for the solder bumps include SnBi solder or the like, for example.

As described above, the semiconductor device 8 can be obtained by mounting the semiconductor chip 80 on the wiring board 5 according to the first embodiment. The wiring board 5 can be suitably used as an interposer substrate for high-speed data communication between a processor and a memory, for example. Further, because the second interconnect structure 2 is thin, the electrical path between the electronic component 12 and the semiconductor chip 80 becomes short. For this reason, the resistance loss in the electrical path between the electronic component 12 and the semiconductor chip 80 can be reduced, thereby improving the power supply efficiency and stabilizing the power supply.

According to the disclosed technique, it is possible to improve dissipation of heat generated by an electronic component in a wiring board embedded with the electronic component.

Although the modifications are numbered with, for example, “first”, “second”, . . . , the ordinal numbers do not imply priorities of the modifications. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A wiring board comprising:
a first interconnect structure including a first interconnect layer, a first insulating layer, and an electronic component embedded in the first insulating layer; and
a second interconnect structure including a second interconnect layer and a second insulating layer, and laminated on one side of the first interconnect structure, wherein:
the second interconnect layer has an interconnect density higher than an interconnect density of the first interconnect layer,
the first interconnect layer includes a pad having a portion exposed from the first insulating layer,
in a plan view, the first insulating layer includes a first region in which the pad is disposed, and a second region located on an outer periphery of the first region, and
the electronic component is disposed in the second region, and is electrically connected to the second interconnect layer.

2. The wiring board as claimed in claim 1, wherein a plurality of the electronic components are disposed in the second region.

3. The wiring board as claimed in claim 2,
wherein the plurality of electronic components are arranged point symmetrically with respect to a center of the first insulating layer in the plan view.

4. The wiring board as claimed in claim 2, wherein:
the first insulating layer has a rectangular shape in the plan view, and
the plurality of electronic components include electronic components disposed at four corners of the rectangular shape.

5. The wiring board as claimed in claim 2, wherein:
the first insulating layer has a rectangular shape in the plan view, and
the plurality of electronic components include electronic components disposed along each side of the rectangle.

6. The wiring board as claimed in claim 1, wherein:
a lower surface of the electronic component and a lower surface of the pad are exposed from a lower surface of the first insulating layer, and
the lower surface of the electronic component and the lower surface of the pad coincide with the lower surface of the first insulating layer.

7. The wiring board as claimed in claim 1, wherein:
the electronic component includes an electrode on a side closer to the second interconnect structure, and the electrode is directly connected to the second interconnect layer.

8. The wiring board as claimed in claim 1, further comprising:
a third interconnect structure including a third interconnect layer and a third insulating layer, and laminated on the other side of the first interconnect structure,
wherein the second interconnect layer has an interconnect density higher than an interconnect density of the third interconnect layer.

9. The wiring board as claimed in claim 8, wherein a plurality of laminates of the first interconnect structure and the second interconnect structure are disposed on one side of the third interconnect structure.

10. A semiconductor device comprising:
the wiring board as claimed in claim 8; and
a semiconductor chip mounted on the second interconnect structure.
